(19) United States
(12) Patent Application Publication
(10) Pub. No.: US 2009/0029559 A1
(43) Pub. Date: Jan. 29, 2009

(54) PHOTO MASK OF SEMICONDUCTOR DEVICE AND METHOD OF FORMING PATTERN USING THE SAME

(76) Inventor: Jae-Hyun Kang, Gangnam-gu (KR)

Correspondence Address: SHERR & VAUGHN, PLLC, 620 HERNDON PARKWAY, SUITE 200, HERNDON, VA, 20170, US

(21) Appl. No.: 12/175,710

(22) Filed: Jul. 18, 2008

(30) Foreign Application Priority Data
Jul. 23, 2007 (KR) 10-2007-0073490

(51) Int. Cl. H01L 21/027; H01L 21/308

(52) U.S. Cl. 438/735; 430/5; 430/313; 257/E21.023; 257/E21.231

(57) ABSTRACT

There is provided a photo mask for forming a specific pattern and a specific pattern formed using the photo mask. Unlike in a related method of forming a specific pattern using a photo mask including cell lines and pad lines, the photo mask is manufactured with cell lines and pad lines, the pad lines each including at least one space line. The photoresist layer is exposed and developed using the photomask to form the photoresist pattern. The etched layer is etched in accordance with the photoresist pattern to form the specific pattern. Therefore, it is possible to improve the pattern uniformity of the semiconductor device and thus to improve yield.

The present application claims priority under 35 U.S.C. 119 to Korean Patent Application No. 10-2007-0073490 (filed on Jul. 23, 2007), which is hereby incorporated by reference in its entirety.

### BACKGROUND

To manufacture a highly integrated semiconductor device, specific patterns must be refined to a very small scale. The critical dimension (CD) and the pitch, obtained by adding a distance between adjacent patterns to the CD, must be refined and minimized. In particular, to form the specific pattern, a hard mask layer and a photoresist layer are formed on an etched layer. The photoresist layer is exposed and developed using a photo mask having the specific pattern to be formed. Then, a hard mask layer is etched in accordance with the photoresist pattern formed by the exposure so that the pattern is transcribed to the etched layer.

However, as design rules of semiconductor devices are changed to accommodate smaller critical dimensions, photoresist patterns stop matching the mask patterns used to create the photoresist patterns. Therefore, it becomes difficult to form a refined pattern having desired CD and a desired pitch.

In semiconductor devices such as DRAM and flash memory, lines and spaces are uniformly replicated. The characteristics of the semiconductor devices are improved only when the size of a pattern to be realized is uniform. However, in the case of the flash memory, since the end of a cell line is formed of a wide pad, it is difficult to maintain the uniformity of the cell line. As illustrated in FIG. 1, in the case of a device of 130 nm, a change of about 3 sigma, or 6.6 nm, is not severe. As illustrated in FIG. 2, in a device with a critical dimension of 90 nm, changes increase at 3 sigma to about 9.4 nm. Since a specific pattern is formed using a photo mask including cell lines and pad lines in the related art, due to the pad line having larger width than the cell line, the uniformity of the pattern deteriorates in accordance with a diffraction phenomenon generated in an exposure process.

### SUMMARY

Embodiments relate to a photo mask of a semiconductor device, and more particularly, to a photo mask of a semiconductor device capable of improving the uniformity of cell lines having a specific pattern in processes of manufacturing a semiconductor device and a method of forming a pattern using the same. Embodiments relate to a photo mask of a semiconductor device including pad lines each having at least one space in order to form the pattern of a semiconductor device. Embodiments relate to forming a specific pattern using the photo mask to improve the pattern uniformity of the semiconductor device and a method of forming a pattern using the same.

Embodiments relate to a photo mask of a semiconductor device for forming a specific pattern of the semiconductor device which includes a plurality of cell lines forming a portion of a specific pattern in a photo mask. A plurality of pad lines are formed at uniform intervals to connect the cell lines to each other and to distinguish the cell lines from each other, each pad line having at least one space line.

According to embodiments, a method of forming a pattern of a semiconductor device using a photo mask of a specific pattern includes manufacturing a photo mask to form a specific pattern including cell lines and pad lines, the pad lines each having at least one space line. The method includes exposing and developing a semiconductor substrate including a photoresist layer using the manufactured photo mask. A layer may be etched on the substrate in accordance with a photoresist pattern formed by the exposure and development to form the specific pattern.

According to embodiments, unlike in a related method of forming a specific pattern using a photo mask including cell lines and pad lines, the photo mask is manufactured with cell lines and pad lines, the pad lines each including at least one space line. The photoresist layer is exposed and developed using the photomask to form the photoresist pattern. The etched layer is etched in accordance with the photoresist pattern to form the specific pattern. Therefore, it is possible to improve the pattern uniformity of the semiconductor device and thus to improve yield.

### DRAWINGS

FIG. 1 illustrates the uniformity of a specific pattern created by a photo mask used for a 130 nm semiconductor device in the related art.

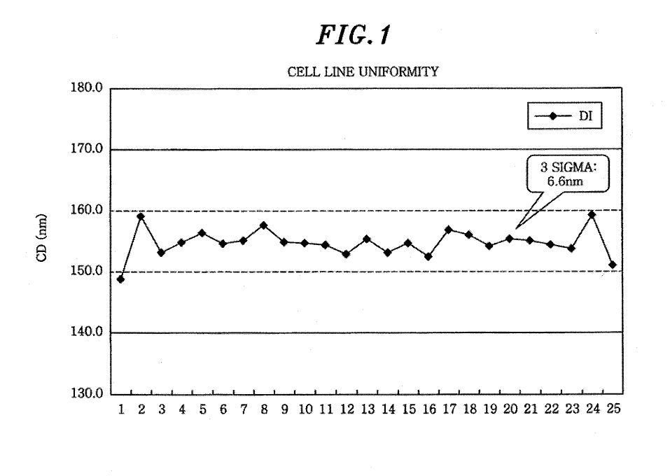

FIG. 2 illustrates the uniformity of a specific pattern created by a photo mask used for a 90 nm semiconductor device in the related art.

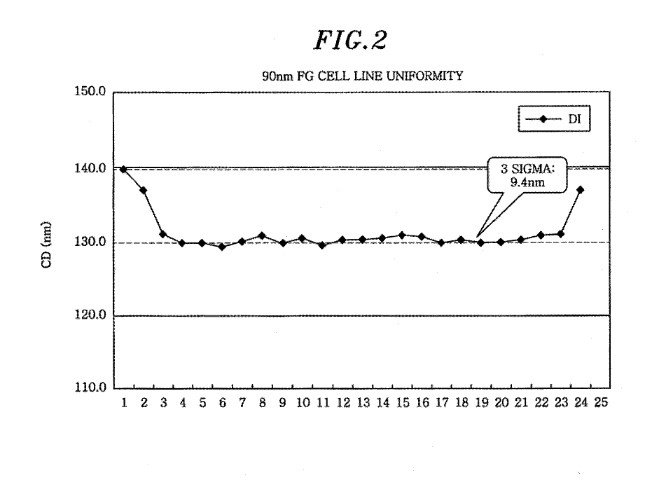

FIG. 3 illustrates a photo mask for forming a specific pattern according to embodiments.

FIG. 4 illustrates the enlarged pad line of a photo mask manufactured according to embodiments.

### DESCRIPTION

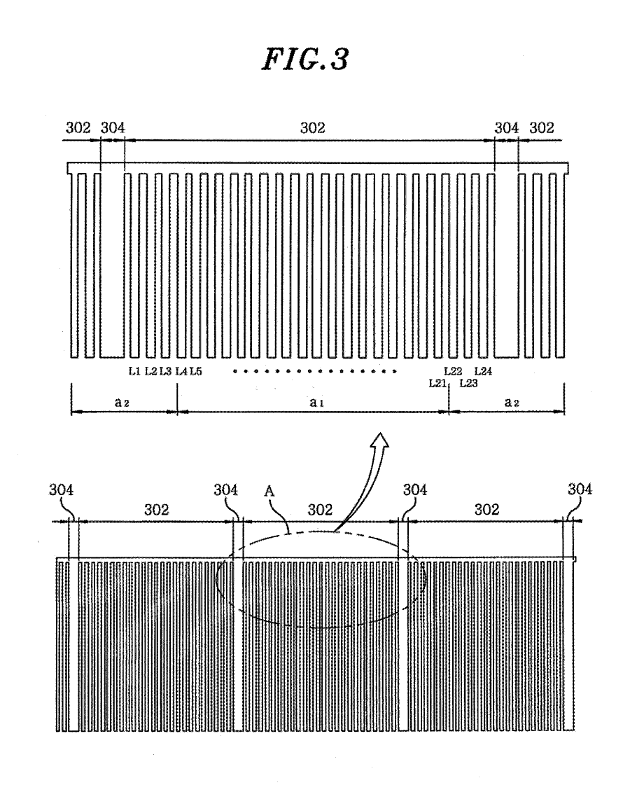

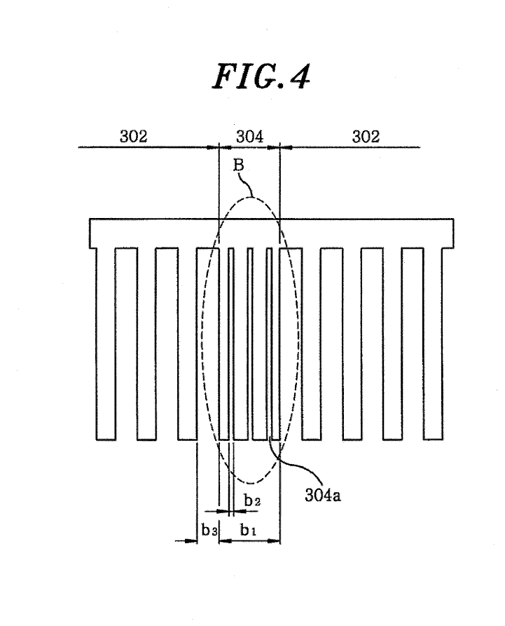

In embodiments, at least one space line is formed in each of the pad lines for distinguishing and connecting the cell lines of a semiconductor device. A specific pattern is formed using the same. The embodiments will overcome the disadvantages of the related art using this technique and variations of it. FIG. 3 illustrates a photo mask for forming a specific pattern according to embodiments. FIG. 4 illustrates the enlarged pad line of a photo mask manufactured according to embodiments. A plurality of cell lines 302 and pad lines 304 are provided and each of the pad lines 304 includes space lines 304a.

Referring to FIGS. 3 and 4, the photo mask according to embodiments includes a plurality of cell lines 302 in which a specific pattern is formed. The pad lines 304 distinguish and connect the plurality of cell lines 302. As illustrated in region A of FIG. 3, pad lines 304 are formed so that a plurality of cell lines 302 are connected to a plurality of cell lines 302 in another region. Such a structure is repeated to form the photo mask.

When region A illustrated in FIG. 3 is described in detail, cell lines 302 of L1, L2, L3, L4, L5, . . . , L21, L22, L23, and L24 are shown and the pad lines 304 for distinguishing different cell line regions are formed on both sides of the cell lines 302.

Here, the width of the pad line 304 is 2.5 times larger than the width of the cell line 302. Due to the pad line 304, in a region a2, unlike in a regional where variation caused by dense line patterns 304 is generated, variation caused by a sparse line pattern is generated. That is, cell lines formed in a first region near an area with pad lines have a sparse pattern and cell lines formed in a second region outside the first region, and without pad lines, have a dense pattern. The diffraction of light around the cell lines (for example, L4 to L21) formed in the regional is different from the diffraction of light around the cell lines (for example, L1 to L3 and L22 to L24) formed in the region a2. A difference in critical dimension (CD) between pitches is large in a process having a large mask error enhancement factor (MEEF), for example, a photolithography process. so that a change in the CD of a semiconductor wafer is also large. Therefore, at least one space line is formed in each of the pad lines which distinguish and connect the cell lines.

The pad lines will be described in detail with reference to FIG. 4. In the pad line formed in a region B, three space lines 304a are formed. At least one space line 304a can be formed in the pad line 304. For example, when the width b1 of pad line 304 is 400 nm, the width b2 of space line 304a may be in a range between 40 nm and 70 nm. The width of the space line 304a can be in the range between 20% and 50% of the width of space region b3 which is between pad line 304 and cell line 302 adjacent thereto. The photo mask having pad line 304 in which the space lines 304a are formed is manufactured so that it is possible to secure the uniformity of the CD of the cell lines when the pattern is formed.

A method of forming a specific pattern using such a photo mask will be described. First, the photo mask including the plurality of cell lines 302 and pad lines 304 is manufactured in order to form the specific pattern. Here, the at least one space line 304a can be formed in the pad line 304 of the photo mask. For example, when the width b1 of the pad line 304 is 400 nm, the width b2 of the space line 304a can be in the range between 40 nm and 70 nm and the width of the space line 304a can be formed in the range between 20% and 50% of the width of space region b3 between the pad line 304 and the adjacent cell line 302.

Then, a semiconductor substrate on which an etched layer (for example, an interlayer insulating layer and a metal layer) is formed may be coated with a photoresist layer. The photoresist layer is exposed and developed by the manufactured photo mask to form a photoresist pattern. The etched layer is etched through the photoresist pattern to form a desired pattern. Therefore, the photoresist pattern is formed using the photo mask having pad lines with at least one space line, and the desired pattern is formed using the same, so that it is possible to improve the uniformity of the CD of the cell lines.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a plurality of cell lines forming a specific pattern in a photo mask; and
a plurality of pad lines formed at uniform intervals to connect the cell lines to each other and to distinguish the cell lines from each other, each pad line having at least one space line.

2. The apparatus of claim 1, wherein the width of a space line is in a range between approximately 20% and 50% of the width of a cell line adjacent to the pad line.

3. The apparatus of claim 1, wherein the pad lines are wider than the cell lines.

4. The apparatus of claim 1, wherein the pad lines are more than twice the width of the cell lines.

5. The apparatus of claim 1, wherein the space line has a width in a range of approximately 10%˜17.5% with respect to the width of the pad lines.

6. The apparatus of claim 1, wherein the space line has a width in a range of approximately 10%˜12.5% with respect to the width of the pad lines.

7. The apparatus of claim 3, wherein the cell lines formed in a first region near the pad lines have a sparse pattern and the cell lines formed in a second region without pad lines have a dense pattern.

8. The apparatus of claim 1, wherein the width of a space line is in a range between approximately 40% and 50% of the width of a cell line adjacent to the pad line.

9. The apparatus of claim 1, wherein the width of a space line is in a range between approximately 30% and 40% of the width of a cell line adjacent to the pad line.

10. The apparatus of claim 1, wherein the pad lines include three space lines.

11. A method comprising:
manufacturing a photo mask to form a specific pattern including cell lines and pad lines, the pad lines each having at least one space line;
exposing and developing a semiconductor substrate including a photoresist layer using the manufactured photo mask; and
etching a layer on the substrate in accordance with a photoresist pattern formed by the exposure and development to form the specific pattern.

12. The method of claim 11, wherein the width of a space line is in a range between approximately 20% and 50% of the width of a cell line adjacent to the pad line.

13. The method of claim 11, wherein the width of a space line is in a range between approximately 40% and 50% of the width of a cell line adjacent to the pad line.

14. The method of claim 11, wherein the width of a space line is in a range between approximately 30% and 40% of the width of a cell line adjacent to the pad line.

15. The method of claim 11, wherein the space line has a width in a range of approximately 10%˜17.5% with respect to the width of the pad lines.

16. The method of claim 11, wherein the space line has a width in a range of approximately 10%˜12.5% with respect to the width of the pad lines.

17. The method of claim 11, comprising forming three space lines in the pad lines.

18. The method of claim 11, comprising forming the pad lines wider than the cell lines.

19. The method of claim 11, comprising forming the pad lines more than twice the width of the cell lines.

20. The method of claim 11, comprising:
forming the cell lines in a sparse pattern in a first region near the pad lines; and
forming the cell lines in a dense pattern in a second region without pad lines.
